(19) United States
(12) Patent Application Publication
(10) Pub. No.: US 2014/0102369 A1
(43) Pub. Date: Apr. 17, 2014

(54) PLASMA SPRAYED DEPOSITION RING ISOLATOR

(71) Applicant: Applied Materials, Inc., Santa Clara, CA (US)

(72) Inventor: Brian T. WEST, San Jose, CA (US)

(21) Appl. No.: 14/103,621

(22) Filed: Dec. 11, 2013

Related U.S. Application Data
(63) Continuation of application No. 11/676,958, filed on Feb. 20, 2007.

(51) Int. Cl. C23C 14/50

(52) U.S. Cl. CPC C23C 14/50
USPC 118/723 R; 118/500; 428/34.6; 204/298.15

(57) ABSTRACT

A substrate processing chamber component including a deposition ring for protecting exposed portions of a substrate support pedestal, wherein the deposition ring includes a metal portion and a ceramic isolator portion. The ceramic isolator portion may be a plasma coated ceramic isolator coating, and the metal portion may be made of stainless steel. The ceramic isolator portion may be made of a ceramic such as alumina, yttria, aluminum nitride, titania, zirconia, and combinations thereof.

### CROSS-REFERENCE TO RELATED APPLICATIONS

This application is a continuation application of co-pending U.S. patent application Ser. No. 11/676,958, filed on Feb. 20, 2007 and now published as US 2008/0196661, which is herein incorporated by reference in its entirety.

### BACKGROUND OF THE INVENTION

1. Field of the Invention

Embodiments of the present invention generally relate to a process chamber for processing a substrate. More specifically, embodiments of the invention relate to deposition and isolator rings for physical vapor deposition or sputtering chambers.

2. Description of the Related Art

In physical deposition processes, particles from a source such as a target may deposit on exposed internal chamber surfaces, including portions of substrate support pedestals not covered by a substrate. Deposition rings have been placed on the exposed portions of the substrate support pedestals in order to protect the uncovered portions of the pedestals. However, arcing between the deposition ring and the pedestal or substrate may result. A separate ceramic isolator ring may be placed between the deposition ring and the pedestal in order to reduce the arcing. However, using a separate isolator ring may be challenging due to gap forces produced by the gaps created between the isolator ring and the deposition ring. Therefore, a need exists for an alternative method of isolating the deposition ring and preventing arcing between a deposition ring and a pedestal.

### SUMMARY OF THE INVENTION

Embodiments of the present invention generally provide for substrate processing components. One embodiment provides a substrate processing chamber component including a deposition ring for protecting exposed portions of a substrate support pedestal, wherein the deposition ring includes a metal portion and a ceramic isolator portion. The ceramic isolator portion may be a plasma coated ceramic isolator coating, and the metal portion may be made of stainless steel. The ceramic isolator portion may be made of a ceramic such as alumina, yttria, aluminum nitride, titania, zirconia, and combinations thereof.

Another embodiment provides a pedestal apparatus comprising a substrate support pedestal having a substrate support surface for supporting a substrate, and a deposition ring, circumscribing the substrate support pedestal for protecting exposed portions of a substrate support, wherein the deposition ring comprises a metal portion and a ceramic isolator portion. The ceramic isolator portion may be a plasma coated ceramic isolator coating, and the metal portion may be made of stainless steel. The ceramic isolator portion may be made of a ceramic such as alumina, yttria, aluminum nitride, titania, zirconia, and combinations thereof.

Another embodiment provides deposition chamber including enclosure walls enclosing a process zone, a pedestal for introducing a substrate into the process zone, wherein the pedestal includes a substrate support pedestal having a substrate support surface for supporting a substrate, and a deposition ring circumscribing the substrate support pedestal for protecting exposed portions of a substrate support, wherein the deposition ring comprises a metal portion and a ceramic isolator portion. The ceramic isolator portion may be a plasma coated ceramic isolator coating, and the metal portion may be made of stainless steel. The ceramic isolator portion may be made of a ceramic such as alumina, yttria, aluminum nitride, titania, zirconia, and combinations thereof.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional side view of a prior art deposition chamber capable of deposition ring modification.

FIG. 2 is an enlarged view of sections of a prior art deposition ring and a prior art isolator ring.

FIGS. 3A-3C are enlarged views of sections of combined deposition rings and an isolator rings according to embodiments of the invention.

FIG. 4 is a cross-sectional view of a plasma torch depositing a coating material on a section of a deposition ring.

### DETAILED DESCRIPTION

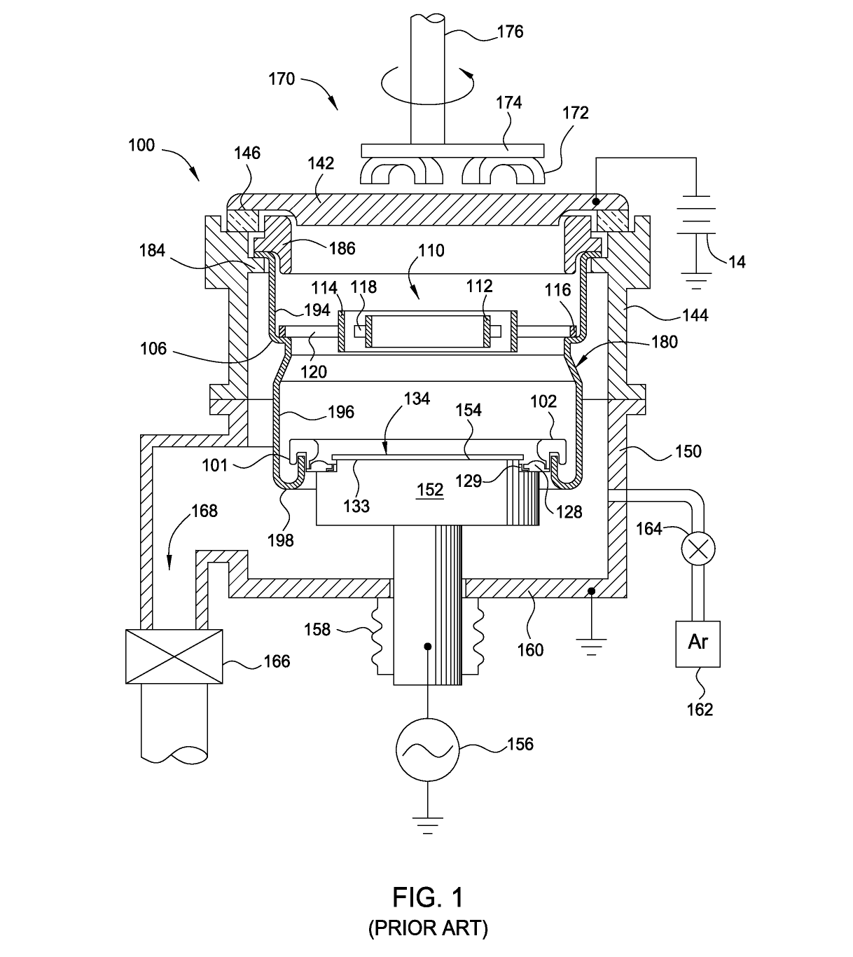

FIG. 1 depicts an example of a process chamber 100 having a deposition ring modified according to embodiments of the invention. The chamber 100 can be a part of a multi-chamber platform (not shown) having a cluster of interconnected chambers connected by a robot arm mechanism that transfers substrates 154 between the chambers 100. In the version shown, the process chamber 100 comprises a sputter deposition chamber, also called a physical vapor deposition or PVD chamber, which is capable of sputter depositing material on a substrate 154, such as one or more of tantalum, tantalum nitride, titanium, titanium nitride, copper, tungsten, tungsten nitride and aluminum. Example of suitable PVD chambers are ALPS® plus and SIP ENCORE™ PVD processing chambers, both commercially available from Applied Materials, Inc., Santa Clara, Calif.

FIG. 1 depicts an example of a long throw PVD chamber. However other PVD chambers are capable of the deposition ring modifications, according to embodiments of the invention. Generally, the long throw PVD chamber 100 contains a sputtering source, such as a target 142, and a substrate support pedestal 152 for receiving a semiconductor substrate 154 thereon and located within a grounded enclosure wall 150, which may be a chamber wall as shown or a grounded shield.

The chamber 100 includes a target 142 supported on and sealed, as by O-rings (not shown), to a grounded conductive aluminum adapter 144 through a dielectric isolator 146. The target 142 comprises the material to be deposited on the substrate 154 surface during sputtering, and may include cobalt, titanium, tantalum, tungsten, molybdenum, platinum, nickel, iron, niobium, palladium, and combinations thereof, which are used in forming metal silicide layers. For example, elemental cobalt, nickel cobalt alloys, cobalt tungsten alloys, cobalt nickel tungsten alloys, doped cobalt and nickel alloys, or nickel iron alloys may be deposited by using alloy targets or multiple targets in the chamber. The target 142 may also include a bonded composite of a metallic surface layer and a backing plate of a more workable metal.

A pedestal 152 supports a substrate 154 to be sputter coated in planar opposition to the principal face of the target 142. The substrate support pedestal 152 has a planar substrate-receiving surface disposed generally parallel to the sputtering surface of the target 142. The pedestal 152 is vertically movable through a bellows 158 connected to a bottom chamber wall 160 to allow the substrate 154 to be transferred onto the pedestal 152 through a load lock valve (not shown) in the lower portion of the chamber 100 and thereafter raised to a deposition position. Processing gas is supplied from a gas source 162 through a mass flow controller 164 into the lower part of the chamber 100.

A controllable DC power source 148 coupled to the chamber 100 may be used to apply a negative voltage or bias to the target 142. An RF power supply 156 may be connected to the pedestal 152 in order to induce a negative DC self-bias on the substrate 154, but in other applications the pedestal 152 is grounded or left electrically floating.

A rotatable magnetron 170 is positioned in back of the target 142 and includes a plurality of horseshoe magnets 172 supported by a base plate 174 connected to a rotation shaft 176 coincident with the central axis of the chamber 100 and the substrate 154. The horseshoe magnets 172 are arranged in closed pattern typically having a kidney shape. The magnets 172 produce a magnetic field within the chamber 100, generally parallel and close to the front face of the target 142 to trap electrons and thereby increase the local plasma density, which in turn increases the sputtering rate. The magnets 172 produce an electromagnetic field around the top of the chamber 100, and magnets 172 are rotated to rotate the electromagnetic field which influences the plasma density of the process to more uniformly sputter the target 142.

The chamber 100 may also be adapted to provide a more directional sputtering of material onto a substrate. In one aspect, directional sputtering may be achieved by positioning a collimator 110 between the target 142 and the substrate support pedestal 152 to provide a more uniform and symmetrical flux of deposition material on the substrate 154.

A metallic ring collimator 110, such as the Grounded Ring collimator, rests on the ledge portion 106 of the bottom shield 180, thereby grounding the collimator 110. The ring collimator 110 includes an outer tubular section and at least one inner concentric tubular section, for example, concentric tubular sections 112 and 114 linked by cross struts 118, 120. The outer tubular section 116 rests on the ledge portion 106 of the bottom shield 180. The use of the bottom shield 180 to support the collimator 110 simplifies the design and maintenance of the chamber 100. At least the two tubular sections 112, 114 are of sufficient height to define high aspect-ratio apertures that partially collimate the sputtered particles. Further, the upper surface of the collimator 110 acts as a ground plane in opposition to the biased target 142, particularly keeping plasma electrons away from the substrate 154.

The bottom shield 180 extends downwardly in an upper generally tubular portion 194 of a first diameter and a lower generally tubular portion 196 of a smaller second diameter to extend generally along the walls of the adapter 144 and the chamber wall 150 to below the top surface of the pedestal 152. It also has a bowl-shaped bottom including a radially extending bottom portion 198 and an upwardly extending inner portion 101 just outside of the pedestal 152. A moveable shutter disk 133 may be positioned on an upper surface 134 of pedestal 152 that can protect the upper surface 134 of the pedestal 152 when the substrate 154 is not present, such as during paste operations. A cover ring 102 rests on the top of the upwardly extending inner portion 101 of the bottom shield 180 when the pedestal 152 is in its lower, loading position.

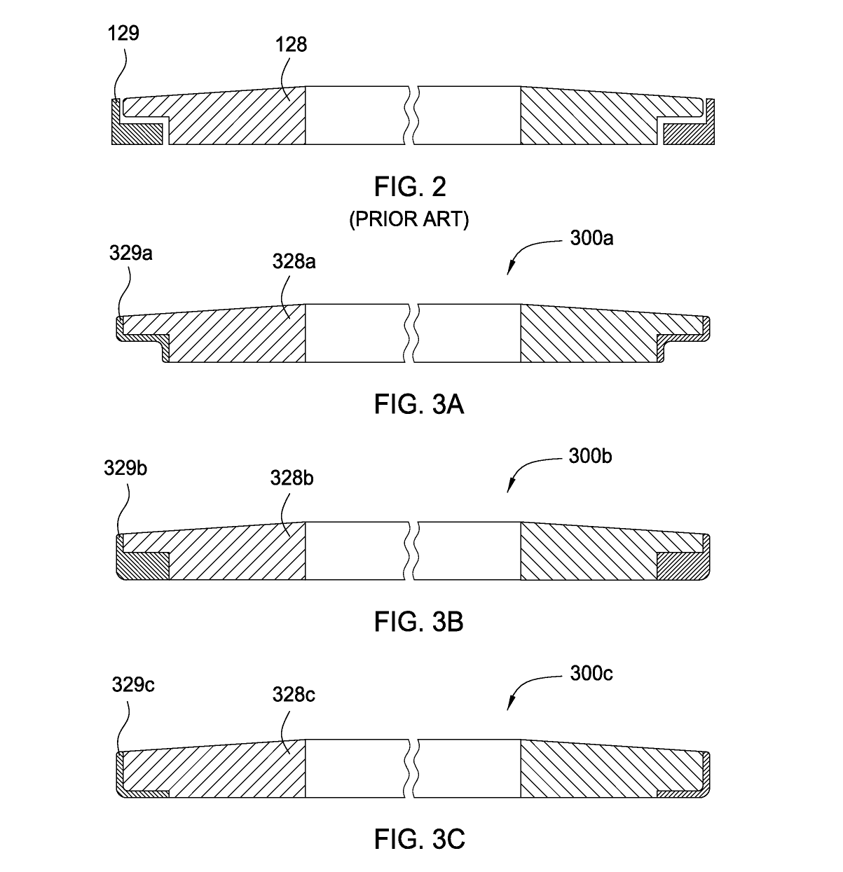

The cover ring 102 and a deposition ring 128 cover at least a portion of the upper surface 134 of the pedestal 152 to inhibit erosion of the pedestal 152 upper surface 134. In one version, the deposition ring 128 may at least partially surround the substrate 154 to protect portions of the pedestal 152 not covered by the substrate 154. In one embodiment, deposition ring 128 may be made of stainless steel or other suitable non-corroding materials. The cover ring 102 may encircle and cover at least a portion of the deposition ring 128, and may reduce the deposition of particles onto both the deposition ring 128 and the underlying sections of pedestal 152. As seen in FIG. 2, the deposition ring 128 may partially overhang a ceramic isolator ring 129 positioned between deposition ring 128 and substrate pedestal 152. Shutter disk 133 or substrate 154 may overhang a top of the ceramic isolator ring 129. Ceramic isolator ring 129 controls or prevents potential arcing between the deposition ring 128 and the substrate pedestal 152 or substrate 154.

FIGS. 3A, 3B, and 3C depict alternatives to the deposition ring 128 and isolator ring 129, according to embodiments of the invention. FIGS. 3A, 3B, and 3C depict portions of cross sections of combined deposition rings and isolator rings 300a, 300b, and 300c, respectively. The deposition/isolator rings 300a, 300b, and 300c may be produced by forming ceramic isolating coatings 329a, 329b, and 329c on sections of the deposition rings 328a, 328b, and 328c, respectively. The ceramic isolating coatings may be produced by plasma spraying. The ceramic isolator coatings controls or prevents potential arcing between the deposition rings and the substrate pedestal 152 or substrate 154.

In one embodiment, the deposition ring 328a may have the same shape and size as deposition ring 128. In this embodiment, the ceramic coating 329a may be conformably deposited on vertical and horizontal surfaces of deposition ring 328a positioned closest to the substrate pedestal 152, as depicted in FIG. 3A.

In another embodiment, the ceramic coating 329b may be deposited in a non-conformably manner so that the ceramic coating forms a layer similar in shape and size of ceramic isolator ring 129 on the vertical and horizontal surfaces of deposition ring 328b positioned closest to the substrate pedestal 152, as depicted in FIG. 3B.

In another embodiment, deposition ring 328c may be shaped so that when the ceramic coating 329c is conformably deposited onto the deposition ring 328c, the ceramic coating 329c forms an L-shaped coating on the vertical and horizontal surfaces of deposition ring 328c positioned closest to the substrate pedestal 152, as depicted in FIG. 3C.

The ceramic isolator coatings of FIGS. 3A-3C may control or prevent potential arcing between the deposition ring and the substrate support or substrate during a deposition process commonly encountered in such processes. Furthermore, instead of separate deposition rings and isolator rings, the two separate parts are combined into one convenient combined deposition and isolator ring. In one embodiment, the deposited ceramic isolator coatings may be permanent. In another embodiment, the deposited ceramic isolator coatings may be reapplied after each recycle of the deposition ring.

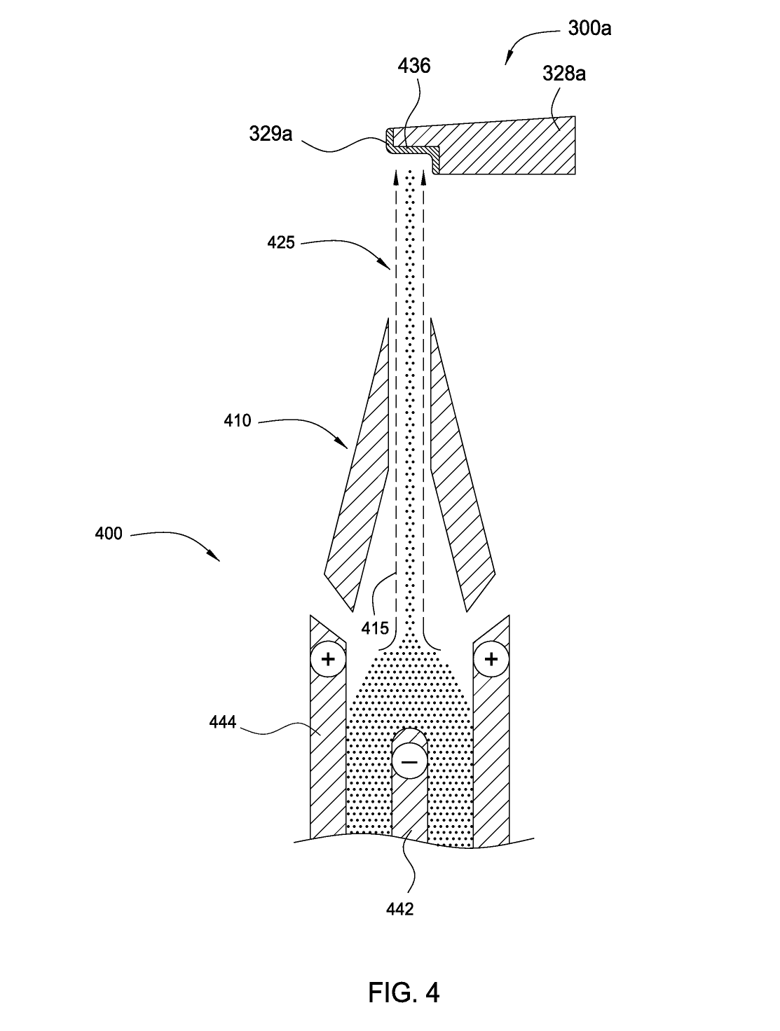

FIG. 4 depicts a method of plasma spraying a ceramic isolating coating onto portions of a deposition ring according to an embodiment of the invention. The ceramic coating 329a is plasma sprayed onto a surface 436 of deposition ring 328a. In plasma spraying, a plasma is formed to atomize or at least partially liquefy a spray of particulate coating material 425 injected through the plasma. For example, the plasma may liquefy the coating material 425 by heating the coating material 425 to a temperature of thousands of degrees Celsius. The liquified droplets of the coating material 425 impinge at high velocities on the surface 436 of deposition ring 328a and rapidly solidify to form a conformal coating 329a, as shown in FIG. 3A.

In one version, a plasma spray torch 400 is used to plasma spray the coating material 425 onto the surface 436 of deposition ring 328a, as shown in FIG. 4. The plasma torch 400 may be mounted on a controllable robotic arm (not shown) to adjust the distance and angle of the plasma torch 400 from the surface 436. Also, the plasma torch 400 may be inside a chamber (not shown) to control the gas environment in which the plasma torch 400 is immersed.

In the plasma torch 400, a carrier gas is flowed between two electrodes, such as a cathode 442 and an anode 444. The carrier gas is suitable to form a high-pressure plasma, such as argon, nitrogen, hydrogen, or helium. Argon may be used because it is chemically inert and because of its ionization characteristics. Adding diatomic gases, such as hydrogen or nitrogen, can increase the enthalpy of the gas. The cathode 442 and anode 444 include materials suitable to generate an electric discharge arc through the plasma, such as metals like tungsten or copper. In one embodiment, the cathode 442 may be made of tungsten and the anode 444 may be made of copper. Additionally, in one version, the anode may be cooled, for example water-cooled, to prevent overheating. The cathode 442 and the anode 444 may be correspondingly shaped to suitably generate an electric arc between them. For example, the cathode 442 may be cone-shaped and the anode 444 may be cylindrical.

An AC high-frequency discharge initiates an electric arc between the cathode 442 and the anode 444 and is sustained using DC power. The electric arc ionizes the carrier gas, creating a high-pressure plasma. The resulting increase in gas temperature increases the volume of the gas and, thus, the pressure and velocity of the gas as it exits a nozzle 410. The coating material 425 is introduced into the gas stream 415 in powder form. The powdered coating material 425 can be introduced just outside the plasma torch 400 or in the diverging exit region of the nozzle 410. The coating material 425 is heated and accelerated by the high-temperature, high-velocity plasma stream.

Operating parameters of the plasma torch 400 are selected to be suitable to adjust the characteristics of the coating material application, such as the temperature and velocity of the coating material 425 as it traverses the path from the plasma torch 400 to the component surface 436. For example, gas flows, power levels, powder feed rate, carrier gas flow, standoff distance from the plasma torch 400 to component surface 436 and the angle of deposition of the coating material 425 relative to the component surface 436 can be adapted to improve the application of the coating material 425 and the subsequent adherence of the coating 420 to sputtered material. For example, the voltage between the cathode 442 and the anode 444 may be selected to be between about 30 Volts and about 60 Volts, such as about 45 Volts. Additionally, the current that flows between the cathode 442 and the anode 444 may be selected to be between about 500 Amps and about 700 Amps, such as about 600 Amps. The power level of the plasma torch 400 is usually in the range between about 12 and about 120 kiloWatts, such as about 80 kiloWatts.

The standoff distance and angle of deposition can be selected to adjust the deposition characteristics of the coating material 425 on the surface 436. For example, the standoff distance and angle of deposition can be adjusted to modify the pattern in which the molten coating material 425 splatters upon impacting the surface 436, to form for example, “pancake” and “lamella” patterns. The standoff distance and angle of deposition can also be adjusted to modify the phase, velocity, or droplet size of the coating material 425 when it impacts the surface 436. In one embodiment, the standoff distance between the plasma torch 400 and surface 436 is between about 2 inches and about 4 inches, such as about 3 inches. The angle of deposition of the coating material 425 onto the surface 436 may be between about 75 degrees and about 105 degrees relative to the surface 436, such as about 90 degrees.

The velocity of the powdered coating material 425 can be adjusted to suitably deposit the coating material 425 on the surface 436. In one embodiment, the velocity of the powdered coating material 425 is between about 300 and about 550 meters/second. Also, the plasma torch 400 may be adapted so that the temperature of the powdered coating material 425 is at least about the melting temperature when the powdered coating material impacts the component surface 436. Temperatures above the melting point can yield a coating 420 of high density and bonding strength. In one embodiment, the bonding strength is between about 29 MPa and about 75 MPa. However, the temperature of the plasma about the electric discharge can also be set to be sufficiently low that the coating material 425 remains molten for a period of time upon impact with the component surface 436. For example, an appropriate period of time may be at least about 0.02 seconds or at least about 0.1 seconds.

The coating material 425 may be chosen from any of several ceramic substances such as alumina (Al₂O₃), yttria (Y₂O₃), aluminum nitride (AlN), titania (TiO₂), zirconia (ZrO₂), and combinations thereof. The positioning on the deposition ring and the thickness of the coating are selected so as to allow the deposition ring to be positioned closer to the substrate pedestal 152, thereby improving the collection of deposited film on the top surface of the deposition ring. The coating thickness may also be tailored to meet requirements of a capacitive coupling of the deposition ring to the substrate pedestal 152, tailored to meet insulation requirements, surface roughness requirements, porosity requirements, and erosion resistance requirements. The porosity of the coating is the ratio of the volume of pore interstices to the volume of its mass. For example, the coating may have a porosity of between about 5% and about 10%, such as about 7%. The coating may also be tailored to prevent flaking and frequent arcing between the deposition ring and the substrate 154 or substrate pedestal 152.

Referring back to FIG. 1, in operation, the substrate 154 is positioned on the substrate support pedestal 152 and plasma is generated in the chamber 100. A long throw distance of at least about 90 mm separates the target 142 and the substrate 154. The substrate support pedestal 152 and the target 142 may be separated by a distance between about 100 mm and about 300 mm for a 200 mm substrate. The substrate support pedestal 152 and the target 142 may be separated by a distance between about 150 mm and about 400 mm for a 300 mm substrate. Any separation between the substrate 154 and target 142 that is greater than 50% of the substrate diameter is considered a long throw processing chamber.

The sputtering process is performed by applying a negative voltage, typically between about 0 V and about 2,400 V, to the target 142 to excite the gas into a plasma state. The D.C. power supply 148 or another power supply may be used to apply a negative bias, for example, between about 0 V and about 700 V, to the substrate support pedestal 152. Ions from the plasma bombard the target 142 to sputter atoms and larger particles onto the substrate 154 disposed below. While the power supplied is expressed in voltage, power may also be expressed as kilowatts or a power density (w/cm²). The amount of power supplied to the chamber 100 may be varied depending upon the amount of sputtering and the size of the substrate 154 being processed.

Processing gas used for the sputtering process is introduced into the processing chamber 100 via the mass flow controller 164. The processing gas includes non-reactive or inert species such as argon (Ar), xenon (Xe), helium (He), or combinations thereof. A vacuum pumping system 166 connected through a pumping port 168 is used to maintain the chamber 100 at a base pressure of less than about 1×10⁻⁶ Torr, such as about 1×10⁻⁸ Torr, but the processing pressure within the chamber 100 is typically maintained at between 0.2 milliTorr and 2 milliTorr, preferably less than 1 milliTorr, for cobalt sputtering.

While the foregoing is directed to embodiments of the present invention, other and further embodiments of the invention may be devised without departing from the basic scope thereof, and the scope thereof is determined by the claims that follow.

1. A substrate processing chamber component, comprising:
a deposition ring for protecting exposed portions of a substrate support pedestal, wherein the deposition ring comprises:
a metal portion having an overhanging portion on one edge; and
a ceramic isolator portion comprising a plasma coated ceramic isolator coating coated on horizontal and vertical surfaces of the one edge of the metal portion of the deposition ring, wherein the overhanging portion partially overhangs the ceramic isolator coating and the ceramic isolator coating consists of yttria (Y₂O₃).

2. The substrate processing chamber component of claim 1, wherein the metal portion comprises stainless steel.

3. The substrate processing chamber component of claim 1, wherein a cross section of the ceramic isolator portion coating has an L-shape.

4. The substrate processing chamber component of claim 1, wherein the horizontal and vertical surfaces on which the ceramic isolator coating is coated are positioned closest to the substrate support pedestal.

5. The substrate processing chamber component of claim 1, wherein the ceramic isolator portion has a porosity of between about 5% and about 10%.

6. The substrate processing chamber component of claim 1, wherein the ceramic isolator portion controls or prevents potential arcing between the deposition ring and the substrate support pedestal.

7. A pedestal apparatus, comprising:
a substrate support pedestal having a substrate support surface for supporting a substrate; and
a deposition ring for protecting exposed portions of a substrate support pedestal, wherein the deposition ring comprises:
a metal portion having an overhanging portion on one edge; and
a ceramic isolator portion comprising a plasma coated ceramic isolator coating coated on horizontal and vertical surfaces of the one edge of the metal portion of the deposition ring, wherein the overhanging portion partially overhangs the ceramic isolator coating and the ceramic isolator coating consists of yttria (Y₂O₃).

8. The pedestal apparatus of claim 7, wherein the metal portion comprises stainless steel.

9. The pedestal apparatus of claim 7, wherein a cross section of the ceramic isolator portion coating has an L-shape.

10. The pedestal apparatus of claim 7, wherein the horizontal and vertical surfaces on which the ceramic isolator coating is coated are positioned closest to the substrate support pedestal.

11. The pedestal apparatus of claim 7, wherein the ceramic isolator portion has a porosity of between about 5% and about 10%.

12. The pedestal apparatus of claim 7, wherein the ceramic isolator portion controls or prevents potential arcing between the deposition ring and the substrate support pedestal.

13. A deposition chamber comprising:
enclosure walls enclosing a process zone; and
a pedestal for introducing a substrate into the process zone, wherein the pedestal comprises a substrate support pedestal having a substrate support surface for supporting a substrate;
a deposition ring for protecting exposed portions of a substrate support pedestal, wherein the deposition ring comprises:
a metal portion having an overhanging portion on one edge; and
a ceramic isolator portion comprising a plasma coated ceramic isolator coating coated on horizontal and vertical surfaces of the one edge of the metal portion of the deposition ring, wherein the overhanging portion partially overhangs the ceramic isolator coating and the ceramic isolator coating consists of yttria (Y₂O₃).

14. The deposition chamber of claim 13, wherein the metal portion comprises stainless steel.

15. The deposition chamber of claim 13, wherein a cross section of the ceramic isolator portion coating has an L-shape.

16. The deposition chamber of claim 13, wherein the horizontal and vertical surfaces on which the ceramic isolator coating is coated are positioned closest to the substrate support pedestal.

17. The deposition chamber of claim 13, wherein the ceramic isolator portion controls or prevents potential arcing between the deposition ring and the substrate support pedestal.
